(19) United States
(12) Patent Application Publication
(10) Pub. No.: US 2024/0306388 A1
(43) Pub. Date: Sep. 12, 2024

(54) SEMICONDUCTOR MEMORY DEVICE

(71) Applicant: Kioxia Corporation, Tokyo (JP)

(72) Inventor: Hiroshi NAKAKI, Yokkaichi Mie (JP)

(73) Assignee: Kioxia Corporation, Tokyo (JP)

(21) Appl. No.: 18/584,044

(22) Filed: Feb. 22, 2024

(30) Foreign Application Priority Data
Mar. 9, 2023 (JP) 2023-036520

(51) Int. Cl. H10B 43/27; H01L 23/00; H01L 25/065; H01L 25/18; H10B 41/27; H10B 80/00

(52) U.S. Cl. CPC H10B 43/27; H01L 24/08; H01L 25/0657; H01L 25/18; H10B 41/27; H10B 80/00; H01L 2224/08145; H01L 2924/1431; H01L 2924/14511

(57) ABSTRACT

A semiconductor memory device includes a stacked body, a plurality of columnar bodies, a plurality of bit lines, a plurality of contacts, and a plurality of dividing portions. The plurality of dividing portions is located separately in the third direction, each extending in the first direction in the stacked body, and dividing one or more gate electrode layers including the lowermost layer of the plurality of gate electrode layers in the third direction, when the one side is the lower side. The plurality of columnar bodies includes five columnar bodies provided in a region between two adjacent dividing portions among the plurality of dividing portions. Regarding each columnar body provided in the five columnar bodies, a separate bit line provided in the plurality of bit lines is present between a bit line provided in the plurality of bit lines and electrically connected to the columnar body, and each bit line provided in the plurality of bit lines and electrically connected to a columnar body adjacent to that columnar body at the shortest interval among the five columnar bodies.

### CROSS-REFERENCE TO RELATED APPLICATION(S)

This application is based upon and claims the benefit of priority from Japanese Patent Application No. 2023-036520, filed Mar. 9, 2023, the entire contents of which are incorporated herein by reference.

### FIELD

Embodiments described herein relate generally to a semiconductor memory device.

### BACKGROUND

A NAND flash memory in which memory cells are arranged three-dimensionally is known.

### DESCRIPTION OF THE DRAWINGS

FIG. 1 is a block diagram showing a part of a configuration of a semiconductor memory device according to a first embodiment;

FIG. 2 is a diagram showing an equivalent circuit of a part of a memory cell array of the first embodiment;

FIG. 3 is a cross-sectional view showing a part of the semiconductor memory device of the first embodiment;

FIG. 4 is an enlarged cross-sectional view of a region surrounded by line F4 of the semiconductor memory device shown in FIG. 3;

FIG. 5 is a cross-sectional view of the semiconductor memory device taken along line F5-F5 shown in FIG. 4;

FIG. 6 is a cross-sectional view of the semiconductor memory device taken along line F6-F6 shown in FIG. 3;

FIG. 7 is an enlarged cross-sectional view of a region surrounded by line F7 of the semiconductor memory device shown in FIG. 6;

FIG. 8 is a cross-sectional view of the semiconductor memory device taken along line F8-F8 shown in FIG. 3;

FIG. 9 is an enlarged cross-sectional view of a region surrounded by line F9 of the semiconductor memory device shown in FIG. 8;

FIG. 10 is an enlarged cross-sectional view of a region surrounded by line F10 of the semiconductor memory device shown in FIG. 9;

FIGS. 11A to 11D are a flowchart showing a flow of a method for manufacturing the semiconductor memory device of the first embodiment;

FIGS. 12A and 12B are diagrams illustrating an advantages of a five-row system of the first embodiment;

FIGS. 13A and 13B are other diagrams illustrating the advantages of the five-row system of the first embodiment;

FIG. 14 is a cross-sectional view showing a part of the semiconductor memory device of a first comparative example;

FIG. 15 is a cross-sectional view showing a part of the semiconductor memory device of a second comparative example;

FIG. 16 is a cross-sectional view showing a part of the semiconductor memory device of a second embodiment;

FIG. 17 is a cross-sectional view showing a part of the semiconductor memory device of a first modification; and

FIG. 18 is a cross-sectional view showing a part of the semiconductor memory device of the second comparative example.

### DETAILED DESCRIPTION

Embodiments provide a semiconductor memory device suitable for high density.

In general, according to at least one embodiment, a semiconductor memory device includes a stacked body, a plurality of columnar bodies, a plurality of bit lines, a plurality of contacts, and a plurality of dividing portions. The stacked body includes a plurality of gate electrode layers and a plurality of insulating layers, and the plurality of gate electrode layers and the plurality of insulating layers are alternately stacked one layer at a time in a first direction. The plurality of columnar bodies extends in the first direction in the stacked body. The plurality of bit lines is located on one side in the first direction with respect to the stacked body, are located in a second direction that intersects with the first direction, and extend in a third direction that intersects with the first direction and the second direction. The plurality of contacts is located between the plurality of columnar bodies and the plurality of bit lines. The plurality of dividing portions is located separately in the third direction, each extending in the first direction in the stacked body, and dividing one or more gate electrode layers including the lowermost layer of the plurality of gate electrode layers in the third direction, when the one side is the lower side. The plurality of columnar bodies includes five columnar bodies which are located alternately in two rows adjacent in the second direction and each extending in the third direction in a region between two adjacent dividing portions of the plurality of dividing portions. Regarding each columnar body provided in the five columnar bodies, a separate bit line provided in the plurality of bit lines is present between a bit line provided in the plurality of bit lines and electrically connected to the columnar body, and each bit line provided in the plurality of bit lines and electrically connected to a columnar body adjacent to that columnar body at the shortest interval among the five columnar bodies.

Hereinafter, semiconductor memory devices according to embodiments will be described with reference to the drawings. In the following description, configurations having the same or similar functions are denoted by the same reference numerals. Further, redundant descriptions of these configurations may be omitted. In the following description, in the reference numerals accompanied by a distinguishing numeral or alphanumeric characters at the end, the numeral and the alphanumeric characters may be omitted if they do not need to be distinguished from each other.

In this application, terms are defined as follows. “Parallel”, “orthogonal”, or “same” may include “substantially parallel”, “substantially orthogonal”, or “substantially the same”, respectively. “Connection” is not limited to mechanical connection, but may include electrical connection. That is, “connection” is not limited to a case where a plurality of elements is directly connected, but may include a case where a plurality of elements is connected with another element interposed therebetween. “Overlapping” is not limited to a case where a plurality of elements is in contact with each other, but may also cover a case where a plurality of elements is separated (a case where projected images of a plurality of elements overlap each other when viewed from a certain direction).

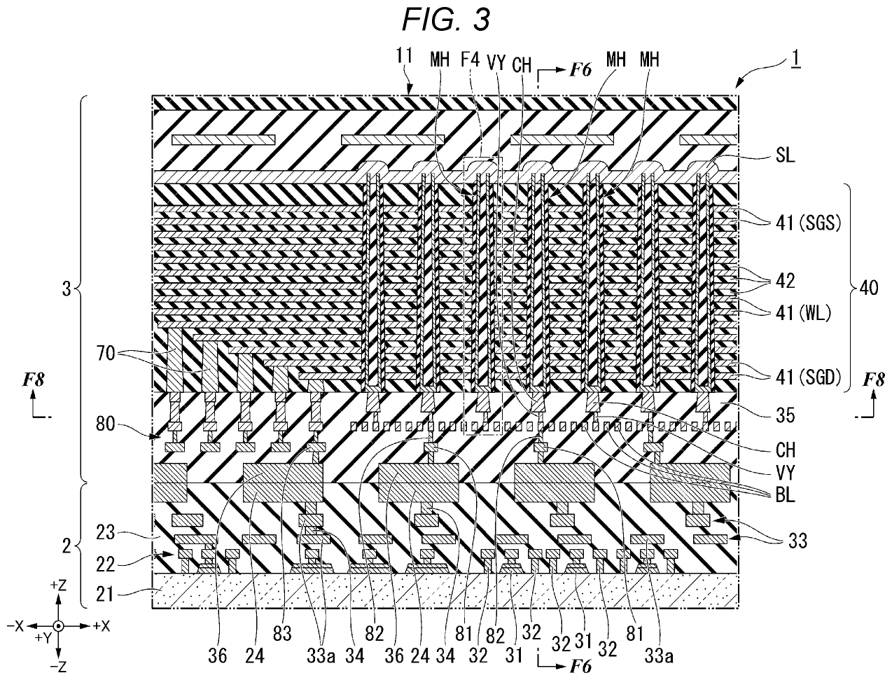

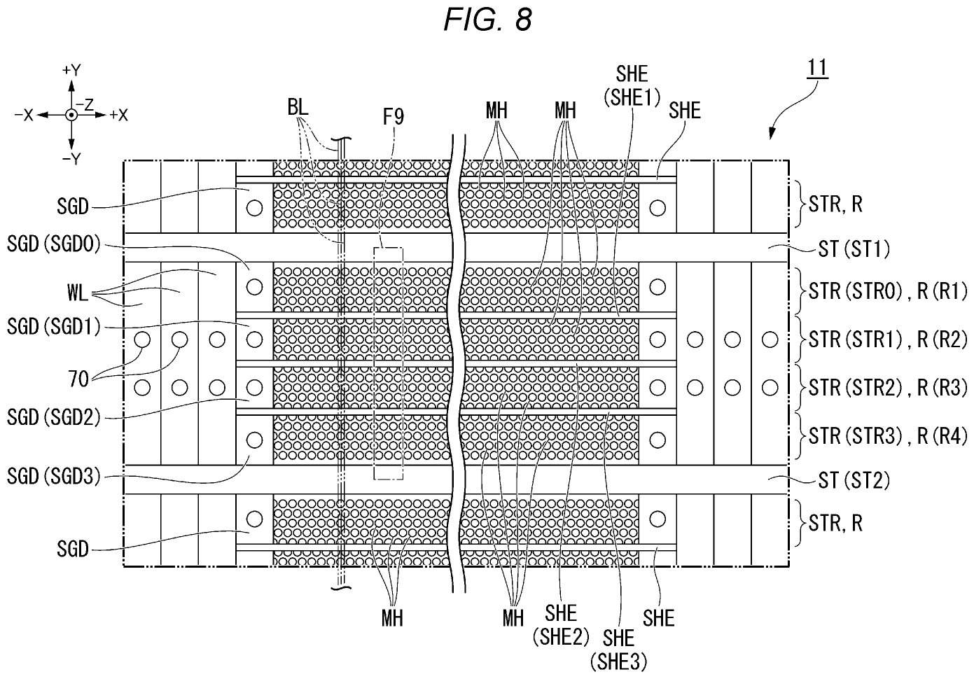

The +X direction, −X direction, +Y direction, −Y direction, +Z direction, and −Z direction are defined as follows. The +X direction is a direction in which a word line WL, which will be described later, extends (see FIG. 8). The −X direction is the opposite direction to the +X direction. When the +X direction and the −X direction are not distinguished, they are simply referred to as the X direction. The +Y direction is a direction that intersects with (for example, is orthogonal to) the X direction. The +Y direction is a direction in which a bit line BL extends (see FIG. 8). The −Y direction is the opposite direction to the +Y direction. When the +Y direction and the −Y direction are not distinguished, they are simply referred to as the Y direction. The +Z direction is a direction that intersects with (for example, is orthogonal to) the X direction and the Y direction. The +Z direction is a direction from the bit line BL, which will be described later, toward a stacked body 40 (see FIG. 3). The −Z direction is the opposite direction to the +Z direction. When the +Z direction and the −Z direction are not distinguished, they are simply referred to as the Z direction.

In the following description, the +Z direction side may be referred to as “upper” and the −Z direction side may be referred to as “lower”. Further, in the following description, the position in the Z direction may be referred to as “height”. However, these expressions are employed for convenience of description and do not define the direction of gravity. The Z direction is an example of a “first direction”. The X direction is an example of a “second direction”. The Y direction is an example of a “third direction”. In the drawings which will be described below, illustrations of configurations not related to the description may be omitted.

### First Embodiment

### <1. Configuration of Semiconductor Memory Device>

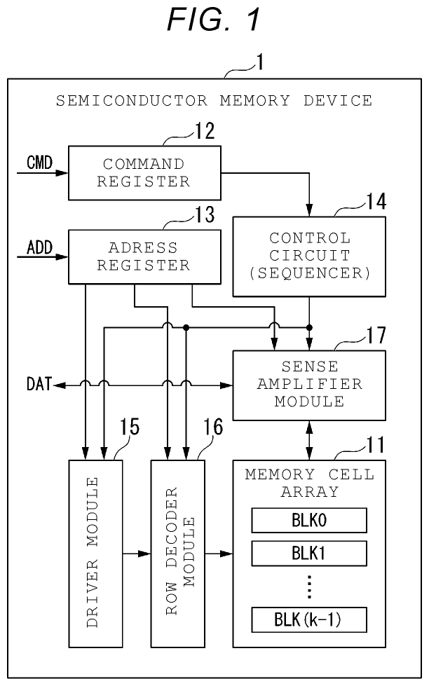

FIG. 1 is a block diagram showing a part of a configuration of a semiconductor memory device 1. The semiconductor memory device 1 is, for example, a nonvolatile semiconductor memory device, and is a NAND flash memory. The semiconductor memory device 1 can be connected to an external host device and is used as a storage space of the host device. The semiconductor memory device 1 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK(k−1) (“k” is an integer equal to or greater than 1). A block BLK is a collection of memory cell transistors. The block BLK is used as a data erase unit. The memory cell array 11 is provided with a plurality of bit lines and a plurality of word lines. Each memory cell transistor is associated with one bit line and one word line.

The command register 12 stores a command CMD that the semiconductor memory device 1 receives from the host device. The address register 13 stores address information ADD that the semiconductor memory device 1 receives from the host device. The address information ADD is used to select a block BLK, a word line, and a bit line. The control circuit 14 controls various operations of the semiconductor memory device 1. For example, the control circuit 14 executes a data write operation, read operation, or erasing operation based on the command CMD stored in the command register 12.

The driver module 15 includes a voltage generation circuit and generates voltages used in various operations of the semiconductor memory device 1. The row decoder module 16 transfers a voltage applied to a signal line corresponding to the selected word line to the selected word line. The sense amplifier module 17 applies a desired voltage to each bit line in a write operation. In a read operation, the sense amplifier module 17 determines a data value stored in each memory cell transistor based on the voltage of each bit line, and transfers a determination result as read data DAT to the host device.

### <2. Electrical Configuration of Memory Cell Array>

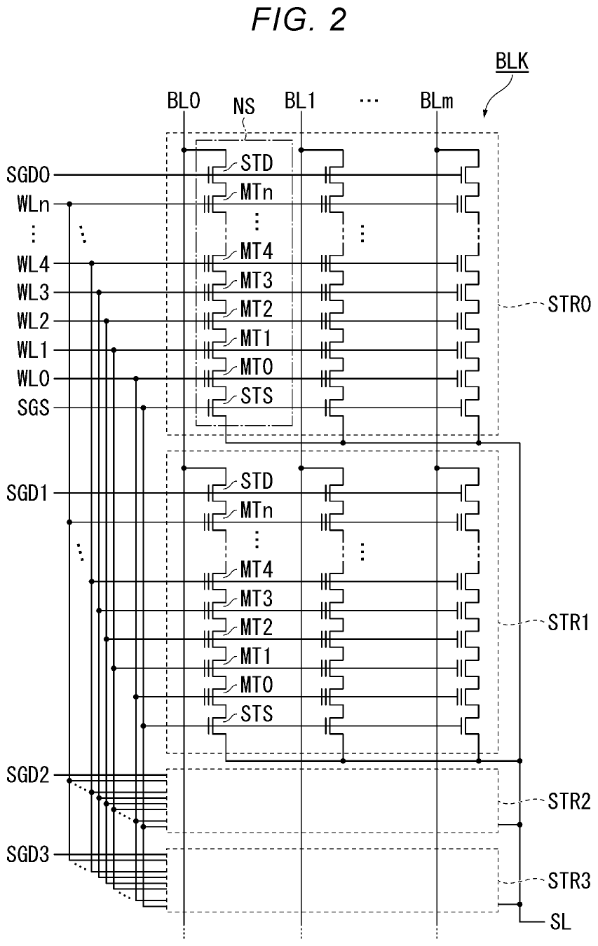

FIG. 2 is a diagram illustrating an equivalent circuit of a part of the memory cell array 11. FIG. 2 illustrates one block BLK provided in the memory cell array 11. The block BLK includes a plurality of (for example, four) strings STR0 to STR3.

Each string STR includes a plurality of NAND strings NS respectively associated with bit lines BL0 to BLm (m is an integer of 1 or more). Each NAND string NS includes, for example, a plurality of memory cell transistors MT0 to MTn (n is an integer of 1 or more), one or more drain-side select transistors STD, and one or more source-side select transistors STS.

In each NAND string NS, the memory cell transistors MT0 to MTn are connected in series. Each memory cell transistor MT includes a control gate and a charge storage portion. The control gate of the memory cell transistor MT is connected to one of word lines WL0 to WLn. In each memory cell transistor MT, charge is stored in the charge storage portion according to the voltage applied to the control gate via the word line WL, and the data value is stored in a non-volatile manner.

A drain of the drain-side select transistor STD is connected to the bit line BL corresponding to the NAND string NS. A source of the drain-side select transistor STD is connected to one end of the memory cell transistors MT0 to MTn connected in series. The control gate of the drain-side select transistor STD is connected to one of drain-side select gate lines SGD0 to SGD3. The drain-side select transistor STD is electrically connected to the row decoder module 16 via the drain-side select gate line SGD. The drain-side select transistor STD connects the NAND string NS and the bit line BL when a predetermined voltage is applied to the corresponding drain-side select gate line SGD.

A drain of the source-side select transistor STS is connected to the other end of the memory cell transistors MT0 to MTn connected in series. A source of the source-side select transistor STS is connected to a source line SL. The control gate of the source-side select transistor STS is connected to the source-side select gate line SGS. The source-side select transistor STS connects the NAND string NS and the source line SL when a predetermined voltage is applied to the source-side select gate line SGS.

In the same block BLK, the control gates of the memory cell transistors MT0 to MTn are commonly connected to corresponding word lines WL0 to WLn, respectively. In the same string STR, the control gates of the drain-side select transistors STD are commonly connected to the corresponding drain-side select gate lines SGD0 to SGD3. The control gates of the source-side select transistors STS are commonly connected to the source-side select gate line SGS. In the memory cell array 11, the bit line BL is shared by NAND strings NS to which the same column address is assigned in the plurality of strings STR.

### <3. Physical Configuration of Semiconductor Memory Device>

Next, the physical configuration of the semiconductor memory device 1 will be described. FIG. 3 is a cross-sectional view showing a part of the semiconductor memory device 1. The semiconductor memory device 1 includes, for example, a first chip 2 and a second chip 3.

### <3.1 First Chip>

The first chip 2 is a circuit chip including a peripheral circuit. The first chip 2 includes, for example, a semiconductor substrate 21, a peripheral circuit 22, an insulating unit 23, and a plurality of pads 24.

The semiconductor substrate 21 is, for example, a substrate that becomes the base of the first chip 2. At least a portion of the semiconductor substrate 21 has a plate shape extending in the X direction and the Y direction. The semiconductor substrate 21 is made of a semiconductor material such as silicon, for example.

The peripheral circuit 22 is a circuit for making the memory cell array 11 described above function. The peripheral circuit 22 includes one or more of the command register 12, the address register 13, the control circuit 14, the driver module 15, the row decoder module 16, and the sense amplifier module 17 described above. The peripheral circuit 22 includes, for example, a plurality of transistors 31, a plurality contacts 32, a plurality of wiring layers 33, and a plurality of vias 34.

The transistor 31 is provided on the semiconductor substrate 21. The contact 32 is electrically conductive, extends in the Z direction, and is in contact with a source region, drain region, or gate electrode of the transistor 31. The plurality of wiring layers 33 are located at a plurality of heights. Each wiring layer 33 includes a plurality of wirings 33a extending in the X direction or the Y direction. The via 34 is an electrical connection portion extending in the Z direction in the first chip 2. The plurality of vias 34 includes, for example, a via 34 that connects two wirings 33a located at different heights, and a via 34 that connects the wiring 33a and the pad 24.

The insulating unit 23 covers the plurality of transistors 31, the plurality of contacts 32, the plurality of wiring layers 33, and the plurality of vias 34. The plurality of pads 24 are provided on the surface of the insulating unit 23. Each pad 24 is electrically connected to the wiring 33a via the via 34.

### <3.2 Second Chip>

The second chip 3 is an array chip including the memory cell array 11. The second chip 3 includes, for example, the memory cell array 11, an insulating unit 35, and a plurality of pads 36. Here, the insulating unit 35 and the plurality of pads 36 will be described, and the memory cell array 11 will be described later.

The insulating unit 35 covers the memory cell array 11. The plurality of pads 36 are provided on the surface of the insulating unit 35. Each pad 36 is electrically connected to a wiring (for example, a wiring 81 or a wiring 83) provided in a wiring unit 80 of the memory cell array 11, which will be described later. In the present embodiment, the plurality of pads 24 of the first chip 2 and the plurality of pads 36 of the second chip 3 are bonded together facing each other, so that the first chip 2 and the second chip 3 are integrated together.

### <4. Physical Configuration of Memory Cell Array>

Next, the physical configuration of the memory cell array 11 will be described.

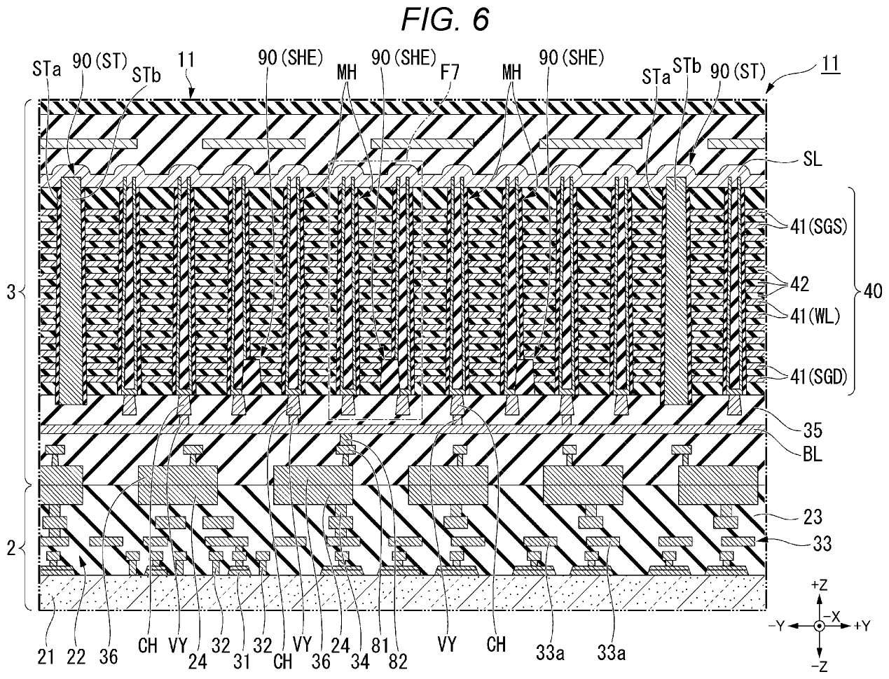

As illustrated in FIG. 3, the memory cell array 11 includes a stacked body 40, the source line SL, a plurality of memory pillars MH, a plurality of bit lines BL, a plurality of contacts CH for memory pillars, a plurality of contacts VY for memory pillars, a contact 70 for conductive layer, the wiring unit 80, and a plurality of dividing portion 90 (see FIG. 6).

### <4.1 Stacked Body>

First, the stacked body 40 will be described.

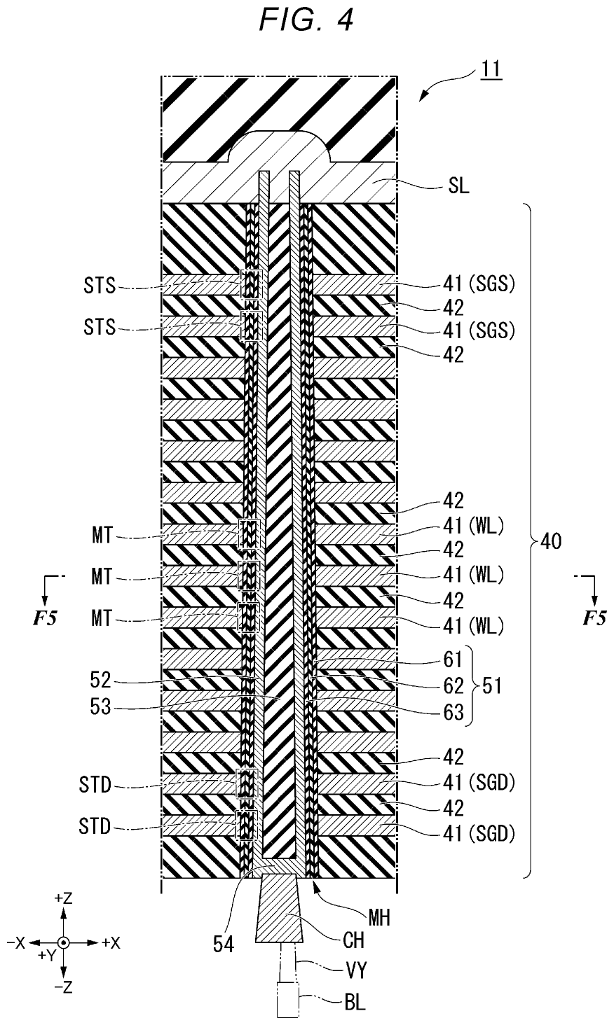

FIG. 4 is an enlarged cross-sectional view of a region surrounded by line F4 of the semiconductor memory device 1 shown in FIG. 3. The stacked body 40 includes a plurality of conductive layers 41 and a plurality of insulating layers 42. The plurality of conductive layers 41 and the plurality of insulating layers 42 are alternately stacked one layer at a time in the Z direction.

The conductive layer 41 extends along the X direction and the Y direction. Each conductive layer 41 is formed of a conductive material such as tungsten or molybdenum. The conductive layer 41 is an example of a “gate electrode layer”.

One or more (for example, a plurality of) conductive layers 41 located below among the plurality of conductive layers 41 function as a drain-side select gate line SGD. The drain-side select gate line SGD is provided in common for a plurality of memory pillars MH arranged in the X direction or the Y direction. An intersection between the drain-side select gate line SGD and a channel layer 52 (described below) of each memory pillar MH functions as the above-mentioned drain-side select transistor STD.

One or more (for example, a plurality of) conductive layers 41 located above among the plurality of conductive layers 41 function as a source-side select gate line SGS. The source-side select gate line SGS is provided in common for a plurality of memory pillars MH arranged in the X direction or the Y direction. An intersection between the source-side select gate line SGS and the channel layer 52 of each memory pillar MH functions as the above-mentioned source-side select transistor STS.

Among the plurality of conductive layers 41, at least a portion of the remaining conductive layer 41 provided between the conductive layers 41 functioning as the drain-side select gate line SGD and the source-side select gate line SGS functions as the word line WL. The word line WL is provided in common to the plurality of memory pillars MH arranged in the X direction and the Y direction. In the present embodiment, an intersection between the word line WL and the channel layer 52 of each memory pillar MH functions as a memory cell transistor MT. The memory cell transistor MT will be described in detail below.

The insulating layer 42 is an interlayer insulating film that is provided between two conductive layers 41 adjacent in the Z direction and insulates those two conductive layers 41. The insulating layer 42 extends along the X direction and the Y direction. The insulating layer 42 is formed of a film containing silicon and oxygen, for example.

### <4.2 Source Line>

The source line SL is located above the stacked body 40. The source line SL is a conductive layer extending in the X direction and the Y direction. The source line SL is formed of a conductive material such as polysilicon or tungsten.

### <4.3 Memory Pillar>

The plurality of memory pillars MH is arranged in the X direction and the Y direction (see FIG. 3). Each memory pillar MH extends in the Z direction in the stacked body 40 and penetrates the stacked body 40. An upper end of the memory pillar MH is in contact with the source line SL. Meanwhile, a lower end of each memory pillar MH is in contact with a contact CH described below. The memory pillar MH is an example of a “columnar body”.

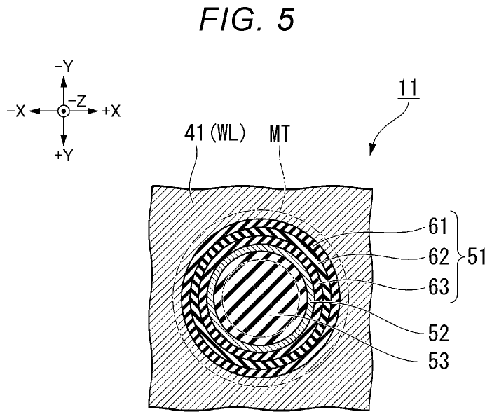

FIG. 5 is a cross-sectional view of the semiconductor memory device 1 taken along line F5-F5 illustrated in FIG. 4. The memory pillar MH includes, for example, a memory film (multilayer film) 51, the channel layer 52, an insulating core 53, and a cap portion 54 (see FIG. 4).

The memory film 51 is provided on the outer peripheral side of the channel layer 52. The memory film 51 is located between the plurality of conductive layers 41 and the channel layer 52. The memory film 51 includes, for example, a block insulating film 61, a charge trap film 62, and a tunnel insulating film 63.

The block insulating film 61 is provided between the plurality of conductive layers 41 and the charge trap film 62. The block insulating film 61 is an insulating film that prevents back tunneling. The back tunneling is a phenomenon in which charges return from the word line WL to the charge trap film 62. The block insulating film 61 is formed in an annular shape and extends in the Z direction. For example, the block insulating film 61 extends over the entire length of the memory pillar MH in the Z direction. The block insulating film 61 is a stacked structure film in which a plurality of insulating films such as a film containing silicon and oxygen or a film containing metal and oxygen are stacked. An example of the film containing metal and oxygen is aluminum oxide. The block insulating film 61 may contain a high dielectric constant material (high-k material) such as silicon nitride or hafnium oxide.

The charge trap film 62 is located between the block insulating film 61 and the tunnel insulating film 63. The charge trap film 62 is formed in an annular shape and extends in the Z direction. The charge trap film 62 extends, for example, over the entire length of the memory pillar MH in the Z direction. The charge trap film 62 is a functional film that has a large number of crystal defects (capture levels) and can trap charges in the crystal defects. The charge trap film 62 is formed of a film containing silicon and nitrogen, for example. A portion of the charge trap film 62 adjacent to each word line WL is an example of a “charge storage unit” that can store information by storing charge.

The tunnel insulating film 63 is provided between the channel layer 52 and the charge trap film 62. The tunnel insulating film 63 has, for example, an annular shape along the outer circumferential surface of the channel layer 52, and extends in the Z direction along the channel layer 52. The tunnel insulating film 63 extends, for example, over the entire length of the memory pillar MH in the Z direction. The tunnel insulating film 63 is a potential barrier between channel layer 52 and charge trap film 62. The tunnel insulating film 63 is formed of a film containing silicon and oxygen, or a film containing silicon, oxygen, and nitrogen.

As a result, a MANOS (Metal-Al-Nitride-Oxide-Silicon) type memory cell transistor MT is formed at the same height as each word line WL by the end portion of the word line WL adjacent to the memory pillar MH, the block insulating film 61, the charge trap film 62, the tunnel insulating film 63, and the channel layer 52. The memory film 51 may have a floating gate type charge storage unit (floating gate electrode) instead of the charge trap film 62 as the charge storage unit. The floating gate electrode is formed of, for example, polysilicon containing impurities.

The insulating core 53 is provided inside the channel layer 52. The insulating core 53 fills at least a portion of the inside of the channel layer 52. The insulating core 53 is formed of a film containing silicon and oxygen. A part of the insulating core 53 may be formed in an annular shape along the inner circumferential surface of the channel layer 52, and have a space (air gap) therein. The insulating core 53 extends in the Z direction. For example, the insulating core 53 extends over most of the memory pillar MH in the Z direction except for the upper end portion of the memory pillar MH (see FIG. 4).

Next, referring back to FIG. 4, the cap portion 54 will be described. The cap portion 54 is provided below the insulating core 53. The cap portion 54 is a semiconductor portion formed of a semiconductor material such as amorphous silicon or polysilicon. The cap portion 54 may be doped with impurities. The cap portion 54 is disposed on the inner peripheral side of the lower end portion of the memory film 51 and is formed integrally with the channel layer 52. The cap portion 54 forms, together with the lower end portion of the channel layer 52, the lower end portion of the memory pillar MH. The contact CH is in contact with the cap portion 54 in the Z direction.

### <4.4 Bit Line>

Next, referring back to FIG. 3, the bit line BL will be described. The bit line BL is a wiring for selecting one memory pillar MH from among the plurality of memory pillars MH. The plurality of bit lines BL is located on the lower side with respect to the stacked body 40. The plurality of bit lines BL is arranged in the X direction at intervals in the X direction. Each bit line BL extends in the Y direction. Each bit line BL extends below a plurality of corresponding memory pillars MH.

Each bit line BL overlaps a plurality of memory pillars MH when viewed from the Z direction (see FIG. 6). Each bit line BL is connected to the channel layer 52 of the memory pillar MH via the contact VY and the contact CH, which will be described below. Thereby, by combining the word line WL and the bit line BL, any memory cell transistor MT can be selected from among the plurality of memory cell transistors MT located three-dimensionally.

### <4.5 Contact CH for Memory Pillar>

The plurality of contacts CH are located between the plurality of memory pillars MH and the plurality of bit lines BL. Each contact CH is an electrical connection portion that electrically connects the contact VY and the memory pillar MH. The contact CH has, for example, a cylindrical shape or a truncated cone shape. When viewed from the Z direction, the outer shape of the contact CH is, for example, the same as the outer shape of the memory pillar MH, or one size smaller than the outer shape of the memory pillar MH.

The contact CH is disposed below the corresponding memory pillar MH and is in contact with the lower end of the memory pillar MH. For example, the contact CH is in contact with the cap portion 54 of the memory pillar MH (see FIG. 4). The connection area between the contact CH and the memory pillar MH (overlapping area when viewed from the Z direction) is larger than the connection area between the contact VY and the contact CH, which will be described below. The contact CH is formed of a metal material such as tungsten or molybdenum, for example. Even if the material of the contact CH and the material of the memory pillar MH are different, good electrical connectivity between the contact CH and the memory pillar MH can be achieved by increasing the connection area between the contact CH and the memory pillar MH to some extent.

### <4.6 Contact VY for Memory Pillar>

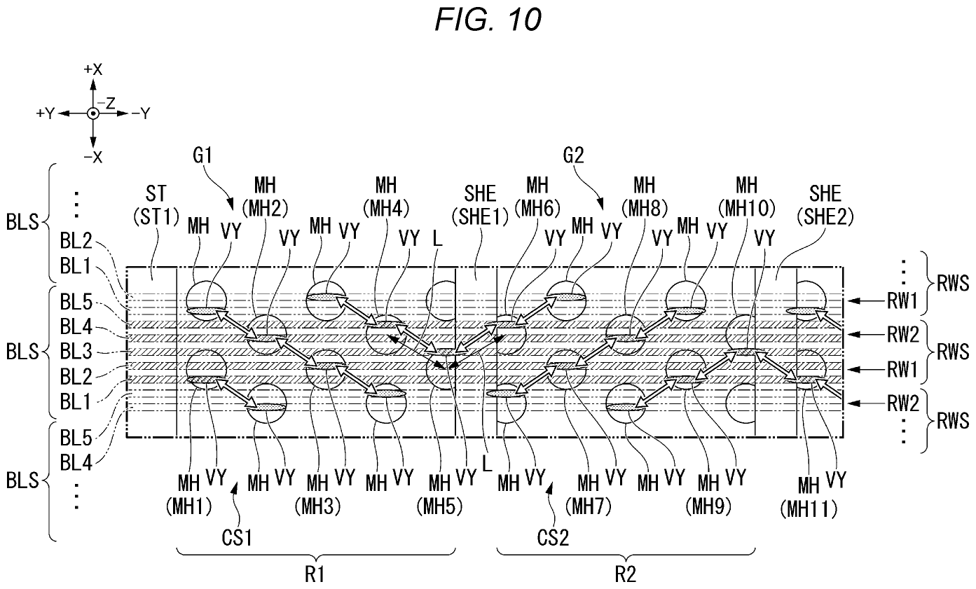

The plurality of contacts VY are located between the plurality of contacts CH and the plurality of bit lines BL. Each contact VY is an electrical connection portion that electrically connects the bit line BL and the contact CH. The width of the contact VY in the X direction is the same as the width of the bit line BL in the X direction (see FIG. 10). The width of the contact VY in the X direction is smaller than the width of the contact CH in the Y direction. When viewed from the Z direction, the contact VY has an elongated shape along the Y direction.

The contact VY is located above the corresponding bit line BL and is in contact with the lower end of the contact CH and the bit line BL. The contact VY is disposed at a position shifted from the center of the contact CH and the center of the memory pillar MH in the X direction. The contact VY is formed of a metal material such as tungsten or molybdenum, for example. The material forming the contact VY is, for example, the same as the material forming the contact CH. Even when the connection area between the contact VY and the contact CH is small, good electrical connectivity between the contact CH and the contact VY is achieved since the material of the contact VY and the material of the contact CH are the same or similar.

### <4.7 Contact for Conductive Layer>

As illustrated in FIG. 3, the contact 70 is an electrical connection portion that electrically connects the conductive layer 41 and a wiring 83 (described below) provided in the wiring unit 80. The plurality of contacts 70 are located, for example, in the stacked body 40 so as to correspond to a step region in which the end portions of the plurality of conductive layers 41 are located in a stepwise manner. The plurality of contacts 70 extend in the Z direction, and have different lengths in the Z direction, for example. The upper end of each contact 70 is in contact with the corresponding conductive layer 41. The upper end of each contact 70 is electrically connected to the corresponding conductive layer 41.

### <4.8 Wiring Unit>

Next, the wiring unit 80 will be described. The wiring unit 80 is located, for example, between the stacked body 40 and the semiconductor substrate 21. The wiring unit 80 includes, for example, a plurality of wirings 81, a plurality of vias 82, and a plurality of wirings 83.

The wiring 81 is an electrical connection portion that electrically connects the bit line BL and the pad 36. For example, the plurality of wirings 81 are located below the plurality of bit lines BL. Each wiring 81 extends, for example, in the X direction or the Y direction. The via 82 is provided between the wiring 81 and the bit line BL to electrically connect the wiring 81 and the bit line BL.

The wiring 83 is an electrical connection portion that electrically connects the contact 70 for conductive layer and the pad 36. The wiring 83 is electrically connected to the conductive layer 41 via the contact 70 for conductive layer. A voltage is applied to the wiring 83 in order to select the conductive layer 41 (word line WL, drain-side select gate line SGD, or source-side select gate line SGS).

### <5. Dividing Portion of Stacked Body>

Next, the dividing portion 90 will be described.

FIG. 6 is a cross-sectional view of the semiconductor memory device 1 taken along line F6-F6 illustrated in FIG. 3. In at least one embodiment, the plurality of dividing portions 90 are provided in the stacked body 40. The plurality of dividing portions 90 are located separately in the Y direction. The plurality of dividing portions 90 each extend in the Z direction in the stacked body 40 and divide one or more conductive layers 41 including the lowermost layer among the plurality of conductive layers 41 in the Y direction. The plurality of dividing portions 90 include, for example, a plurality of dividing portions ST and a plurality of dividing portions SHE.

### <5.1 Dividing Portion ST>

The dividing portion ST is a wall portion that divides the stacked body 40 in the Y direction. The plurality of dividing portions ST are located separately in the Y direction. The dividing portion ST extends in the Z direction, penetrates the stacked body 40, and also extends in the X direction. That is, the dividing portion ST is a wall portion along the Z direction and the X direction. The dividing portion ST divides each of all the conductive layers 41 provided in the stacked body 40 in the Y direction. The dividing portion ST includes, for example, an insulating portion STa and a conductive portion STb.

The insulating portion STa extends in the Z direction and penetrates the stacked body 40. The insulating portion STa divides each of the plurality of conductive layers 41 provided in the stacked body 40 in the Y direction. The insulating portion STa is formed of a film containing silicon and oxygen, for example.

The conductive portion STb is provided inside the insulating portion STa. The conductive portion STb extends in the Z direction and penetrates the stacked body 40. The upper end of conductive portion STb is in contact with the source line SL. The conductive portion STb is formed of a conductive material such as tungsten or molybdenum. The conductive portion STb is, for example, an electrical connection portion that connects the source line SL and the wiring in the memory cell array 11.

### <5.2 Dividing Portion SHE>

The dividing portion SHE is a dividing portion shallower in the Z direction than the dividing portion ST, and is a wall portion that divides the lower end portion of the stacked body 40 in the Y direction. The plurality of dividing portions SHE are located separately in the Y direction. In at least one embodiment, a plurality of (for example, three) dividing portions SHE exists between two dividing portions ST adjacent to each other in the Y direction. The dividing portion SHE is provided at the lower end portion of the stacked body 40, extends halfway through the stacked body 40 in the Z direction, and also extends in the X direction. That is, the dividing portion SHE is a wall portion along the Z direction and the X direction.

The dividing portion SHE penetrates some conductive layers 41 including the lowermost layer among the plurality of conductive layers 41, and divides the some conductive layer 41 in the Y direction. For example, the dividing portion SHE penetrates through each of all the conductive layers 41 that function as the drain-side select gate line SGD. Meanwhile, the dividing portion SHE does not reach the conductive layer 41 functioning as the word line WL. The dividing portion SHE divides only the conductive layer 41 functioning as the drain-side select gate line SGD in the Y direction. The dividing portion SHE is formed of, for example, a film containing silicon and oxygen.

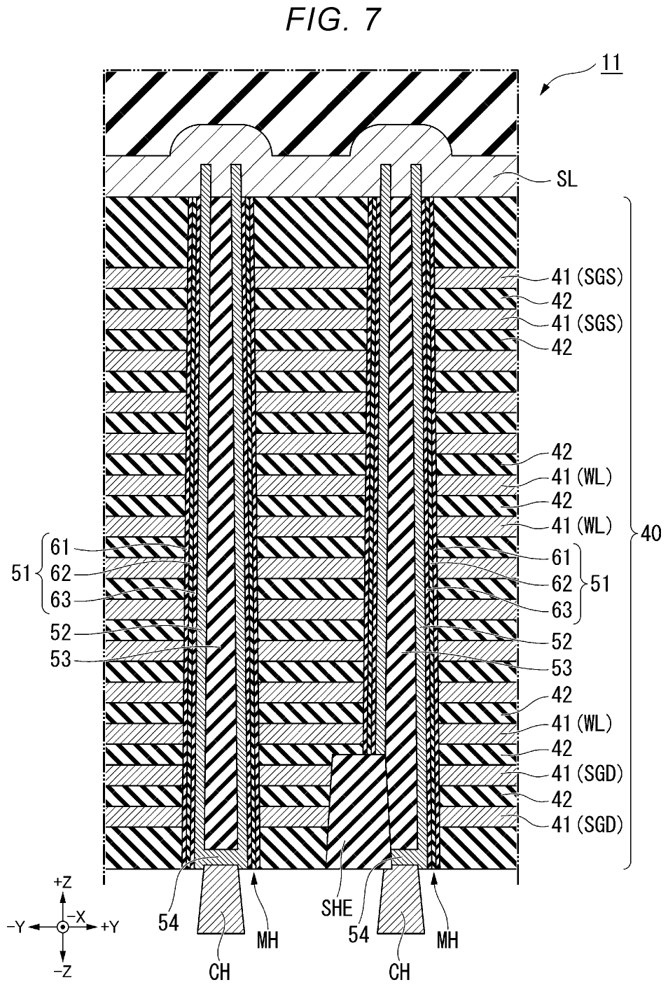

FIG. 7 is an enlarged cross-sectional view of a region surrounded by line F7 of the semiconductor memory device 1 illustrated in FIG. 6. In the present embodiment, the dividing portion SHE bites into a part of the lower end portion of the memory pillar MH. That is, when viewed from the Z direction, a part of the dividing portion SHE and a part of the memory pillar MH overlap. Thereby, as will be described in detail later, when viewed from the Z direction, the plurality of memory pillars MH is located at equal intervals regardless of the presence or absence of the dividing portion SHE.

FIG. 8 is a cross-sectional view of the semiconductor memory device 1 taken along line F8-F8 illustrated in FIG. 3. In at least one embodiment, the conductive layer 41 corresponding to the drain-side select gate line SGD is divided in the Y direction by the dividing portion ST and the dividing portion SHE. As a result, a drain-side select gate line SGD extending in the X direction is formed. Thereby, the region divided by the dividing portion ST or the dividing portion SHE corresponds to one string STR.

In other words, the stacked body 40 has a plurality of regions R defined by the plurality of dividing portions ST and the plurality of dividing portions SHE. The plurality of regions R includes, for example, a first region R1, a second region R2, a third region R3, and a fourth region R4. The first region R1, the second region R2, the third region R3, and the fourth region R4 exist between two dividing portions ST adjacent to each other in the Y direction.

In at least one embodiment, three dividing portions SHE (dividing portions SHE1, SHE2, SHE3) exist between two dividing portions ST (dividing portions ST1, ST2) adjacent to each other in the Y direction. The dividing portion SHE1, the dividing portion SHE2, and the dividing portion SHE3 are arranged in this order from the dividing portion ST1 to the dividing portion ST2. Thereby, the first region R1 is defined between the dividing portion ST1 and the dividing portion SHE1. The second region R2 is defined between the dividing portion SHE1 and the dividing portion SHE2. The third region R3 is defined between the dividing portion SHE2 and the dividing portion SHE3. The fourth region R4 is defined between the dividing portion SH3 and the dividing portion ST2. That is, the first region R1, the second region R2, the third region R3, and the fourth region R4 are arranged in this order in the Y direction. The first region R1 and the second region R2 are adjacent to each other. The third region R3 is located on the opposite side of the first region R1 with respect to the second region R2 and is adjacent to the second region R2.

### <6. Connection Structure Between Memory Pillar and Bit Line>

Next, the connection structure between the memory pillar MH and the bit line BL will be described.

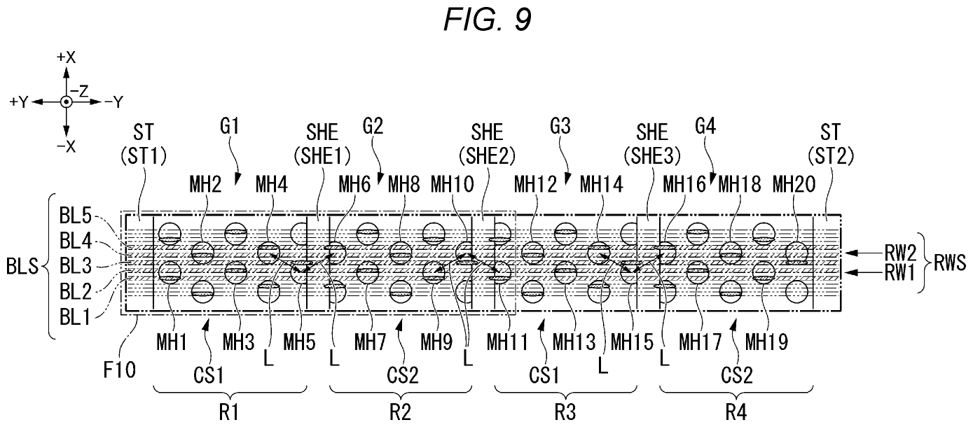

FIG. 9 is an enlarged cross-sectional view of a region surrounded by line F9 of the semiconductor memory device 1 illustrated in FIG. 8. It should be noted that in FIG. 9, for convenience of description, illustration of the contacts CH is omitted and some bit lines BL are hatched.

In at least one embodiment, the respective memory pillars MH are located such that the memory pillars MH are located at the corners and centers of a plurality of virtual hexagons laid out in a hexagonal lattice. In at least one embodiment, the plurality of memory pillars MH is located by the arrangement structure in which five memory pillars MH are arranged in the Y direction (hereinafter referred to as a “five-row system arrangement structure”) in a region R between two adjacent dividing portions 90 (i.e., dividing portions ST or dividing portions SHE). It should be noted that in the present application, the phrase “a plurality of memory pillars is arranged in a specific direction” is not limited to the case where a plurality of memory pillars MH is arranged in a straight line in the above specific direction, but may also include a case where a plurality of memory pillars MH is arranged in a staggered pattern along the above specific direction. That is, “a plurality of memory pillars is arranged in the Y direction” means that the positions of the plurality of memory pillars MH in the Y direction are different, and the positions of the plurality of memory pillars MH in the X direction may be different from each other. This definition also applies to the expression “a plurality of memory pillars is arranged in a specific direction” in the present application.

In at least one embodiment, one structural unit is a connection structure between a bit line set BLS including five bit lines BL adjacent to each other in the X direction and a plurality of memory pillars MH corresponding to the five bit lines BL. The above connection structure exists repeatedly in the X direction for every five bit lines BL. Therefore, the connection structure corresponding to one bit line set BLS will be described in detail below.

### <6.1 Arrangement of Memory Pillars>

The plurality of memory pillars MH includes, for example, memory pillars MH of a first group G1, memory pillars MH of a second group G2, memory pillars MH of a third group G3, and memory pillars MH of a fourth group G4.

The memory pillars MH of the first group G1 are located in the first region R1. The memory pillars MH of the first group G1 include, for example, a first memory pillar MH1 (first columnar body), a second memory pillar MH2 (second columnar body), a third memory pillar MH3 (third columnar body), a fourth memory pillar MH4 (fourth columnar body), and a fifth memory pillar MH5 (fifth columnar body). The first memory pillar MH1, the second memory pillar MH2, the third memory pillar MH3, the fourth memory pillar MH4, and the fifth memory pillar MH5 are arranged in this order in the Y direction.

In at least one embodiment, the first to fifth memory pillars MH1 to MH5 are located separately into a first row RW1 and a second row RW2 provided in one row set RWS. The first row RW1 and the second row RW2 are two rows that are adjacent to each other in the X direction and extend in the Y direction. The first to fifth memory pillars MH1 to MH5 are alternately located in the first row RW1 and the second row RW2. For example, the first memory pillar MH1, the third memory pillar MH3, and the fifth memory pillar MH5 are located in the first row RW1. The second memory pillar MH2 and the fourth memory pillar MH4 are located in the second row RW2. In the present embodiment, the first to fifth memory pillars MH1 to MH5 partially overlap each other when viewed from the Y direction.

The memory pillars MH of the second group G2 are located in the second region R2. The memory pillars MH of the second group G2 include, for example, a sixth memory pillar MH6 (sixth columnar body), a seventh memory pillar MH7 (seventh columnar body), an eighth memory pillar MH8 (eighth columnar body), a ninth memory pillar MH9 (ninth columnar body), and a tenth memory pillar MH10 (tenth columnar body). The sixth memory pillar MH6, the seventh memory pillar MH7, the eighth memory pillar MH8, the ninth memory pillar MH9, and the tenth memory pillar MH10 are arranged in this order in the Y direction.

In at least one embodiment, the sixth to tenth memory pillars MH6 to MH10 are located separately into the first row RW1 and the second row RW2 provided in the row set RWS. The sixth to tenth memory pillars MH6 to MH10 are alternately located in the first row RW1 and the second row RW2. For example, the sixth memory pillar MH6, the eighth memory pillar MH8, and the tenth memory pillar MH10 are located in the second row RW2. The seventh memory pillar MH7 and the ninth memory pillar MH9 are located in the first row RW1. In the present embodiment, the sixth to tenth memory pillars MH6 to MH10 partially overlap each other when viewed from the Y direction.

The memory pillars MH of the third group G3 are located in the third region R3. The memory pillars MH of the third group G3 include, for example, an eleventh memory pillar MH11 (eleventh columnar body), a twelfth memory pillar MH12 (twelfth columnar body), a thirteenth memory pillar MH13 (thirteenth columnar body), a fourteenth memory pillar MH14 (fourteenth columnar body), and a fifteenth memory pillar MH15 (fifteenth columnar body). The eleventh memory pillar MH11, the twelfth memory pillar MH12, the thirteenth memory pillar MH13, the fourteenth memory pillar MH14, and the fifteenth memory pillar MH15 are arranged in this order in the Y direction.

In the present embodiment, the eleventh to fifteenth memory pillars MH11 to MH15 are located separately into the first row RW1 and the second row RW2 provided in the row set RWS. The eleventh to fifteenth memory pillars MH11 to MH15 are alternately located in the first row RW1 and the second row RW2. For example, the eleventh memory pillar MH11, the thirteenth memory pillar MH13, and the fifteenth memory pillar MH15 are located in the first row RW1. The twelfth memory pillar MH12 and the fourteenth memory pillar MH14 are located in the second row RW2. In the present embodiment, the eleventh to fifteenth memory pillars MH11 to MH15 partially overlap each other when viewed from the Y direction.

The memory pillars MH of the fourth group G4 are located in the fourth region R4. The memory pillars MH of the fourth group G4 are, for example, a 16th memory pillar MH16 (16th columnar body), a 17th memory pillar MH17 (17th columnar body), an 18th memory pillar MH18 (18th columnar body), a 19th memory pillar MH19 (19th columnar body), and a 20th memory pillar MH20 (20th columnar body). The 16th memory pillar MH16, the 17th memory pillar MH17, the 18th memory pillar MH18, the 19th memory pillar MH19, and the 20th memory pillar MH20 are arranged in this order in the Y direction.

In at least one embodiment, the 16th to 20th memory pillars MH16 to MH20 are located separately into the first row RW1 and the second row RW2 provided in the row set RWS. The 16th to 20th memory pillars MH16 to MH20 are alternately located in the first row RW1 and the second row RW2. For example, the 16th memory pillar MH16, the 18th memory pillar MH18, and the 20th memory pillar MH20 are located in the second row RW2. The 17th memory pillar MH17 and the 19th memory pillar MH19 are located in the first row RW1. In the present embodiment, the 16th to 20th memory pillars MH16 to MH20 partially overlap each other when viewed from the Y direction.

As described above, in the present embodiment, the dividing portion SHE and the memory pillar MH are located at high density so that a part of the dividing portion SHE and a part of the memory pillar MH overlap when viewed from the Z direction. Therefore, when viewed from the Z direction, the center-to-center distance L between two memory pillars MH adjacent by the shortest distance in one region R is the same as the center-to-center distance L between two memory pillars MH that are separated into two regions R with the dividing portion SHE interposed therebetween and are adjacent by the shortest distance.

For example, the fifth memory pillar MH5 and the sixth memory pillar MH6 are located separately on both sides of the dividing portion SHE1. When viewed from the Z direction, the dividing portion SHE1 overlaps with a portion of the fifth memory pillar MH5 and a portion of the sixth memory pillar MH6. When viewed from the Z direction, the center-to-center distance L between the fifth memory pillar MH5 and the sixth memory pillar MH6 is the same as the center-to-center distance L between the fourth memory pillar MH4 and the fifth memory pillar MH5.

Similarly, the tenth memory pillar MH10 and the eleventh memory pillar MH11 are located separately on both sides of the dividing portion SHE2. When viewed from the Z direction, the dividing portion SHE2 overlaps with a portion of the tenth memory pillar MH10 and a portion of the eleventh memory pillar MH11. When viewed from the Z direction, the center-to-center distance L between the tenth memory pillar MH10 and the eleventh memory pillar MH11 is the same as the center-to-center distance L between the ninth memory pillar MH9 and the tenth memory pillar MH10.

### <6.2 Arrangement of Bit Lines>

The plurality of bit lines BL includes a first bit line BL1, a second bit line BL2, a third bit line BL3, a fourth bit line BL4, and a fifth bit line BL5. The first bit line BL1, the second bit line BL2, the third bit line BL3, the fourth bit line BL4, and the fifth bit line BL5 are arranged in this order in the X direction.

### <6.3 Connection Structure>

FIG. 10 is an enlarged cross-sectional view of a region surrounded by line F10 of the semiconductor memory device 1 illustrated in FIG. 9. It should be noted that in FIG. 10, for convenience of description, illustration of the contacts CH is omitted and some bit lines BL are hatched.

The first memory pillar MH1 overlaps the first bit line BL1 when viewed from the Z direction, and is electrically connected to the first bit line BL1 via the contact VY. The second memory pillar MH2 overlaps the fourth bit line BL4 when viewed from the Z direction, and is electrically connected to the fourth bit line BL4 via the contact VY. The third memory pillar MH3 overlaps the second bit line BL2 when viewed from the Z direction, and is electrically connected to the second bit line BL2 via the contact VY. The fourth memory pillar MH4 overlaps the fifth bit line BL5 when viewed from the Z direction, and is electrically connected to the fifth bit line BL5 via the contact VY. The fifth memory pillar MH5 overlaps the third bit line BL3 when viewed from the Z direction, and is electrically connected to the third bit line BL3 via the contact VY. Hereinafter, the connection structure between the five memory pillars MH and the five bit lines BL in the first region R1 described above will be referred to as a first connection structure CS1.

The sixth memory pillar MH6 overlaps the fifth bit line BL5 when viewed from the Z direction, and is electrically connected to the fifth bit line BL5 via the contact VY. The seventh memory pillar MH7 overlaps the second bit line BL2 when viewed from the Z direction, and is electrically connected to the second bit line BL2 via the contact VY. The eighth memory pillar MH8 overlaps the fourth bit line BL4 when viewed from the Z direction, and is electrically connected to the fourth bit line BL4 via the contact VY. The ninth memory pillar MH9 overlaps the first bit line BL1 when viewed from the Z direction, and is electrically connected to the first bit line BL1 via the contact VY. The tenth memory pillar MH10 overlaps the third bit line BL3 when viewed from the Z direction, and is electrically connected to the third bit line BL3 via the contact VY. Hereinafter, the connection structure between the five memory pillars MH and the five bit lines BL in the second region R2 described above will be referred to as a second connection structure CS2.

In at least one embodiment, among the plurality of regions R, in the odd-numbered region R (first region R1, third region R3) when counting in the Y direction with the first region R1 as the “first”, five memory pillars MH and five bit lines BL are connected by the above-described first connection structure CS1. Therefore, for example, in the connection structure in the third region R3, the first to fifth memory pillars MH1 to MH5 in the description of the connection structure in the first region R1 may be read as the eleventh to fifteenth memory pillars MH11 to MH15, respectively.

Meanwhile, among the plurality of regions R, in the even-numbered region R (second region R2, fourth region R4) when counting in the Y direction with the first region R1 as the “first”, five memory pillars MH and five bit lines BL are connected by the second connection structure C2 described above. Therefore, for example, in the connection structure in the fourth region R4, the sixth to tenth memory pillars MH6 to MH10 in the description of the connection structure in the second region R2 may be read as the sixteenth to twentieth memory pillars MH16 to MH20, respectively.

In at least one embodiment, for each memory pillar MH provided in the first to twentieth memory pillars MH1 to MH20, another bit line BL exists between the bit line BL electrically connected to the memory pillar MH and each bit line BL that is electrically connected to a memory pillar MH adjacent to the memory pillar MH at the shortest interval (shortest pitch) among the first to twentieth memory pillars MH1 to MH20.

For example, regarding the second memory pillar MH2, among the first to twentieth memory pillars MH1 to MH20, the first memory pillar MH1 and the third memory pillar MH3 exist as memory pillars MH adjacent to the second memory pillar MH2 at the shortest distance (shortest pitch). Therefore, between the fourth bit line BL4 electrically connected to the second memory pillar MH2 and the first bit line BL1 electrically connected to the first memory pillar MH1, there are the second bit line BL2 and the third bit line BL3 as another bit line BL. Similarly, between the fourth bit line BL4 electrically connected to the second memory pillar MH2 and the second bit line BL2 electrically connected to the third memory pillar MH3, there is the third bit line BL3 as another bit line BL.

For example, regarding the third memory pillar MH3, among the first to twentieth memory pillars MH1 to MH20, the second memory pillar MH2 and the fourth memory pillar MH4 exist as memory pillars MH adjacent to the third memory pillar MH3 at the shortest distance (shortest pitch). Therefore, between the second bit line BL2 electrically connected to the third memory pillar MH3 and the fourth bit line BL4 electrically connected to the second memory pillar MH2, there is the third bit line BL3 as another bit line BL. Similarly, between the second bit line BL2 electrically connected to the third memory pillar MH3 and the fifth bit line BL5 electrically connected to the fourth memory pillar MH4, there are the third bit line BL3 and the fourth bit line BL4 as another bit line BL.

### <7. Manufacturing Method>

Next, a method for manufacturing the semiconductor memory device 1 will be described.

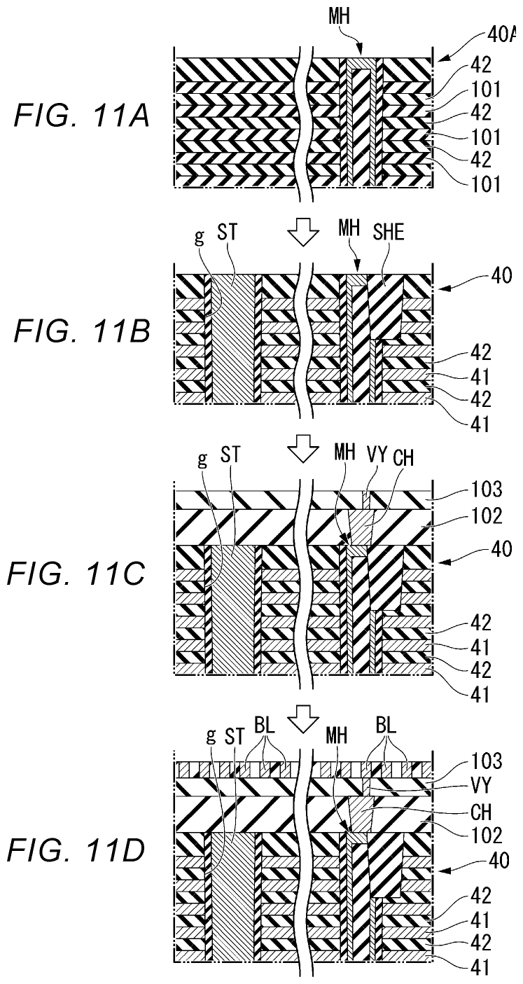

FIG. 11A to 11D are a flowchart illustrating the flow of the method for manufacturing the semiconductor memory device 1. Below, processes related to forming the dividing portion SHE, the contact CH, the contact VY, and the bit line BL will be described. Other details of the manufacturing process are described in, for example, JP-A-2022-41054. This literature is incorporated in the present application by reference in its entirety.

First, as illustrated in FIG. 11A, the insulating layers 101 and the insulating layers 42 are alternately stacked to form a stacked body 40A. The insulating layer 101 is a sacrifice layer that will be replaced by the conductive layer 41 in a replacement step that will be described later. The insulating layer 101 is formed of a film containing silicon and nitrogen, for example. Next, a hole for providing a memory pillar MH is formed in the stacked body 40A, and the memory pillar MH is formed inside the hole.

Next, as illustrated in FIG. 11B, a dividing portion ST and a dividing portion SHE are formed. For example, a groove g for providing the dividing portion ST is formed in the stacked body 40A. Next, a replacement step is performed. That is, the insulating layer 101 is removed through the groove g by wet etching. Next, the material for the conductive layer 41 is supplied to the space from which the insulating layer 101 has been removed, and the conductive layer 41 is formed. Next, a dividing portion ST is formed inside the groove g. Next, a groove for providing the dividing portion SHE is formed in the stacked body 40A, and the dividing portion SHE is formed inside the groove.

Next, as illustrated in FIG. 11C, contacts CH and contacts VY are formed. For example, the insulating layer 102 is stacked on the stacked body 40. Next, a hole for providing the contact CH is formed in the insulating layer 102, and the contact CH is formed inside the hole. Next, an insulating layer 103 is stacked on the insulating layer 102 and the contact CH. Next, a hole for providing the contact VY is formed in the insulating layer 103, and the contact VY is formed inside the hole.

Next, as illustrated in FIG. 11D, a bit line BL is formed above the contact VY. Thereafter, the wiring unit 80 is formed, thereby completing the second chip 3. Then, the vertical direction of the second chip 3 is reversed, and the first chip 2 and the second chip 3 are bonded together, thereby forming the semiconductor memory device 1.

### <8. Advantages>

### <8.1 Advantages of Five-Row System Arrangement Structure>

First, the advantages of the five-row system arrangement structure will be described.

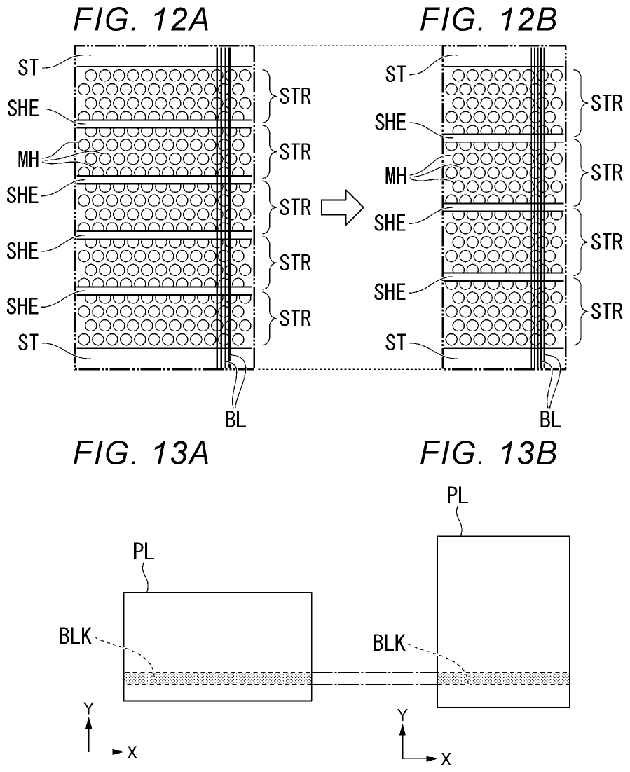

FIGS. 12A and 12B are diagrams illustrating the advantages of the five-row system. FIG. 12A shows a four-row system arrangement structure, which is a comparative example. The four-row system arrangement structure is an arrangement structure in which four memory pillars MH are arranged in the Y direction between two adjacent dividing portions 90 (i.e., dividing portions ST or dividing portions SHE). FIG. 12B illustrates the five-row system arrangement structure of at least one embodiment. In the arrangement structures in FIGS. 12A and 12B, the distance between the two dividing portions ST and the arrangement structure of the plurality of memory pillars MH are the same.

In recent years, as the semiconductor memory device 1 has become more highly stacked, the block size (the number of memory cell transistors MT provided in each block BLK) has been increasing. A block BLK is a storage unit defined between two adjacent dividing portions ST. As the block size increases, erasing operations take longer, making it difficult to increase the speed of the semiconductor memory device 1.

Therefore, in at least one embodiment, a five-row system arrangement structure is provided. According to the five-row system arrangement structure, the number of strings STRs provided in one block BLK can be reduced while the number of memory transistors MT provided in each string STR is the same, compared to the four-row system arrangement structure. Therefore, the block size can be made smaller in the five-row system arrangement structure compared to the four-row system arrangement structure. If the block size can be reduced, the speed of the semiconductor memory device 1 can be increased by shortening the erasing operation time.

FIGS. 13A and 13B are other diagrams illustrating the advantage of the five-row system. FIG. 13A illustrates a plane PL having a four-row system arrangement structure, which is a comparative example. FIG. 13B illustrates a plane PL having a five-row system arrangement structure according to the present embodiment. The plane PL is a unit of physical structure provided in the memory cell array 11 as a configuration including a plurality of blocks BLK. In the arrangement structure in FIGS. 13A and 13B, the number of memory cell transistors MT provided in the plane PL is the same.

In the five-row system arrangement structure according to at least one embodiment, since the number of memory transistors MT provided in each string STR is the same as the number of memory transistors MT provided in each string STR with the four-row system, compared to the four-row system arrangement structure, the length of the plane PL in the X direction is set to be ⅘ shorter. As a result, in the five-row system arrangement structure of the present embodiment, the number of blocks BLK increases by 1.25 times compared to the four-row system arrangement structure.

### <8.2 Advantages of Connection Structure of Present Embodiment>

When a five-row system arrangement structure is provided, the contacts VY tend to be located closely, and if the distance between the plurality of contacts VY is not sufficiently large, a problem such as a short circuit may occur between the plurality of contacts VY. For this reason, when providing a five-row system arrangement structure, it becomes difficult to achieve high density.

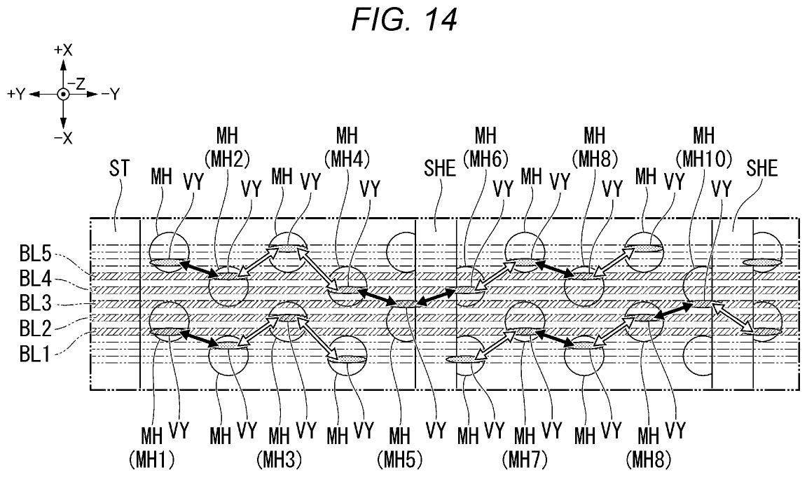

FIG. 14 is a cross-sectional view showing a part of the semiconductor memory device of a first comparative example. The semiconductor memory device of the first comparative example has a five-row system arrangement structure in which five memory pillars MH are arranged in the Y direction in each region R, similarly to the first embodiment. However, the connection structure between the five bit lines BL and the plurality of memory pillars MH is different from the connection structure of the first embodiment described above.

According to the connection structure of the first comparative example, for one or more memory pillars MH provided in the first to twentieth memory pillars MH1 to MH20, there is a location in which no other bit line BL exists between the bit line BL electrically connected to the memory pillar MH and each bit line BL that is electrically connected to a memory pillar MH adjacent to the memory pillar MH at the shortest interval among the first to twentieth memory pillars MH1 to MH20 (see the black arrow in FIG. 14). For example, in the example illustrated in FIG. 14, there is no other bit line BL between the third bit line BL3 electrically connected to the fifth memory pillar MH5 and the fourth bit line BL4 electrically connected to the sixth memory pillar MH6. Therefore, the distance between the contact VY corresponding to the fifth memory pillar MH5 and the contact VY corresponding to the sixth memory pillar MH6 is small, which may cause a problem.

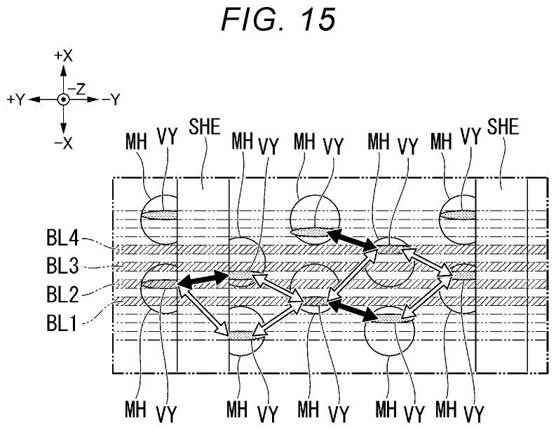

FIG. 15 is a cross-sectional view showing a part of the semiconductor memory device of a second comparative example. The semiconductor memory device of the second comparative example has a four-row system arrangement structure in which four memory pillars MH are arranged in the Y direction in each region R. In the four-row system arrangement structure, no matter what kind of connection structure is adopted, for one or more memory pillars MH provided in the first to twentieth memory pillars MH1 to MH20, there is a location in which no other bit line BL exist between the bit line BL electrically connected to the memory pillar MH and each bit line BL that is electrically connected to a memory pillar MH adjacent to the memory pillar MH at the shortest interval among the first to twentieth memory pillars MH1 to MH20 (see the black arrow in FIG. 15).

On the other hand, in at least one embodiment, for each memory pillar MH provided in the first to twentieth memory pillars MH1 to MH20, another bit line BL exists between the bit line BL electrically connected to the memory pillar MH and each bit line BL that is electrically connected to a memory pillar MH adjacent to the memory pillar MH at the shortest interval among the first to twentieth memory pillars MH1 to MH20 (see FIG. 9). This is a unique arrangement structure in the five-row system that does not exist in the four-row system arrangement structure. By having such a configuration, it is possible to provide a five-row system arrangement structure and to avoid densely locating the contacts VY, and to provide a sufficiently large distance between the plurality of contacts VY. Thereby, the semiconductor memory device 1 suitable for high density can be obtained.

### Second Embodiment

Next, the second embodiment is described. It should be noted that the configuration of the second embodiment other than those described below is the same as the configuration of the first embodiment.

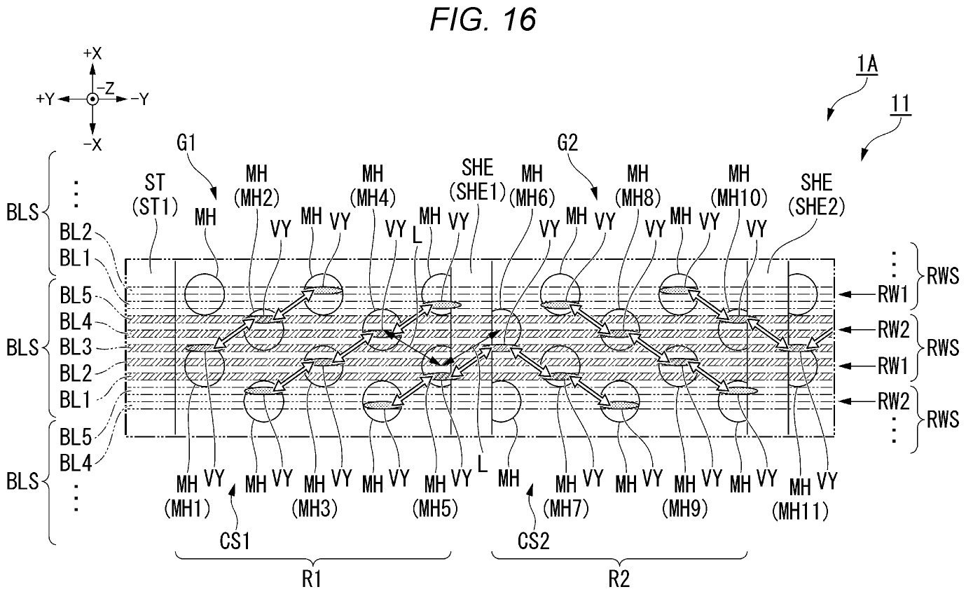

FIG. 16 is a cross-sectional view illustrating a part of a semiconductor memory device 1A of the second embodiment. In at least one embodiment, the first memory pillar MH1 overlaps the third bit line BL3 when viewed from the Z direction, and is electrically connected to the third bit line BL3 via the contact VY. The second memory pillar MH2 overlaps the fifth bit line BL5 when viewed from the Z direction, and is electrically connected to the fifth bit line BL5 via the contact VY. The third memory pillar MH3 overlaps the second bit line BL2 when viewed from the Z direction, and is electrically connected to the second bit line BL2 via the contact VY. The fourth memory pillar MH4 overlaps the fourth bit line BL4 when viewed from the Z direction, and is electrically connected to the fourth bit line BL4 via the contact VY. The fifth memory pillar MH5 overlaps the first bit line BL1 when viewed from the Z direction, and is electrically connected to the first bit line BL1 via the contact VY. In at least one embodiment, the above connection structure is referred to as a first connection structure CS1.

The sixth memory pillar MH6 overlaps the third bit line BL3 when viewed from the Z direction, and is electrically connected to the third bit line BL3 via the contact VY. The seventh memory pillar MH7 overlaps the first bit line BL1 when viewed from the Z direction, and is electrically connected to the first bit line BL1 via the contact VY. The eighth memory pillar MH8 overlaps the fourth bit line BL4 when viewed from the Z direction, and is electrically connected to the fourth bit line BL4 via the contact VY. The ninth memory pillar MH9 overlaps the second bit line BL2 when viewed from the Z direction, and is electrically connected to the second bit line BL2 via the contact VY. The tenth memory pillar MH10 overlaps the fifth bit line BL5 when viewed from the Z direction, and is electrically connected to the fifth bit line BL5 via the contact VY. Hereinafter, the above connection structure will be referred to as a second connection structure CS2.

In at least one embodiment, among the plurality of regions R, in the odd-numbered region R (first region R1, third region R3) when counting in the Y direction with the first region R1 as the “first”, five memory pillars MH and five bit lines BL are connected by the above-described first connection structure CS1. Therefore, for example, in the connection structure in the third region R3, the first to fifth memory pillars MH1 to MH5 in the description of the connection structure in the first region R1 may be read as the eleventh to fifteenth memory pillars MH11 to MH15, respectively.

Meanwhile, among the plurality of regions R, in the even-numbered region R (second region R2, fourth region R4) when counting in the Y direction with the first region R1 as the “first”, five memory pillars MH and five bit lines BL are connected by the second connection structure CS2 described above. Therefore, for example, in the connection structure in the fourth region R4, the sixth to tenth memory pillars MH6 to MH10 in the description of the connection structure in the second region R2 may be read as the sixteenth to twentieth memory pillars MH16 to MH20, respectively.

According to such a configuration, similarly to the first embodiment, it is possible to provide a five-row system arrangement structure and to avoid densely locating the contacts VY, and to provide a sufficiently large distance between the plurality of contacts VY. Thereby, the semiconductor memory device 1 suitable for high density can be obtained. In should be noted that the connection structure of the second embodiment is a structure that is symmetrical to the connection structure of the first embodiment. That is, by rotating the connection structure of the first embodiment by 180 degrees, the connection structure of the second embodiment can be obtained.

### Modifications of Embodiments

Next, some modifications will be described. The modification described below are applicable to the first embodiment and the second embodiment described above. It should be noted that the configuration other than those described below is the same as the configuration of the first embodiment.

### First Modification

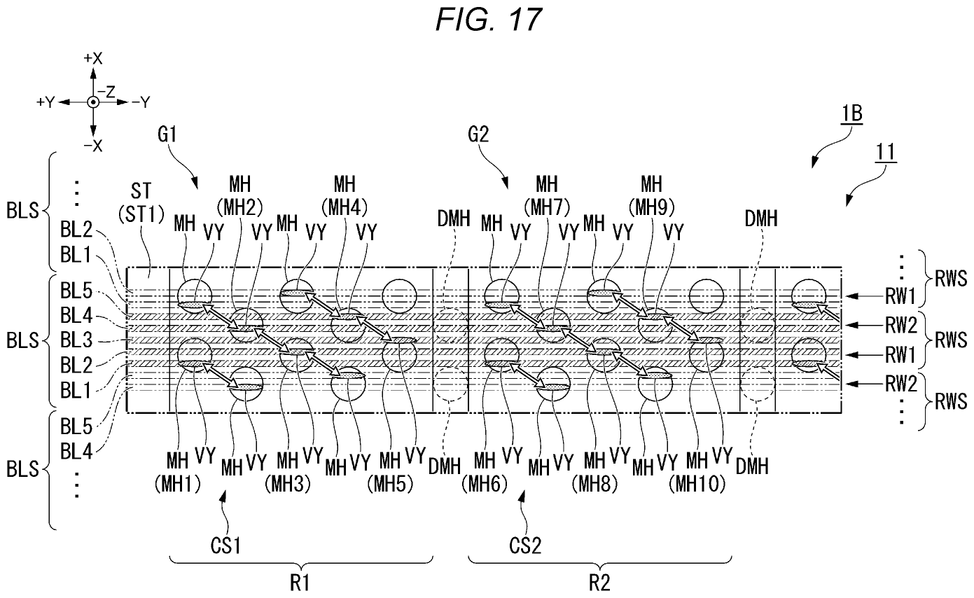

FIG. 17 is a cross-sectional view illustrating a part of a semiconductor memory device 1B of the first modification. In at least one embodiment, a dummy memory pillar DMH is arranged between the memory pillar MH of the first group G1 and the memory pillar MH of the second group G2. Similarly, a dummy memory pillar DMH is located between the memory pillar MH of the second group G2 and the memory pillar MH of the third group G3. A dummy memory pillar DMH is located between the memory pillar MH of the third group G3 and the memory pillar MH of the fourth group G4. The dummy memory pillar DMH has the same structure as the memory pillar MH, but is a structure that does not function as the memory pillar MH. In at least one embodiment, the dividing portion SHE overlaps the dummy memory pillar DMH and extends in the X direction when viewed from the Z direction.

In the first modification, for example, in the second region R2, five memory pillars MH and five bit lines BL are connected by the above-described first connection structure CS1, similarly to the first region R1. Therefore, for example, in the connection structure in the second region R2, the first to fifth memory pillars MH1 to MH5 in the description of the connection structure in the first region R1 may be read as the sixth to tenth memory pillars MH6 to MH10, respectively. It should be noted that the connection structure provided in the second region R2 may be a second connection structure CS2 instead of the first connection structure CS1.

### Second Modification

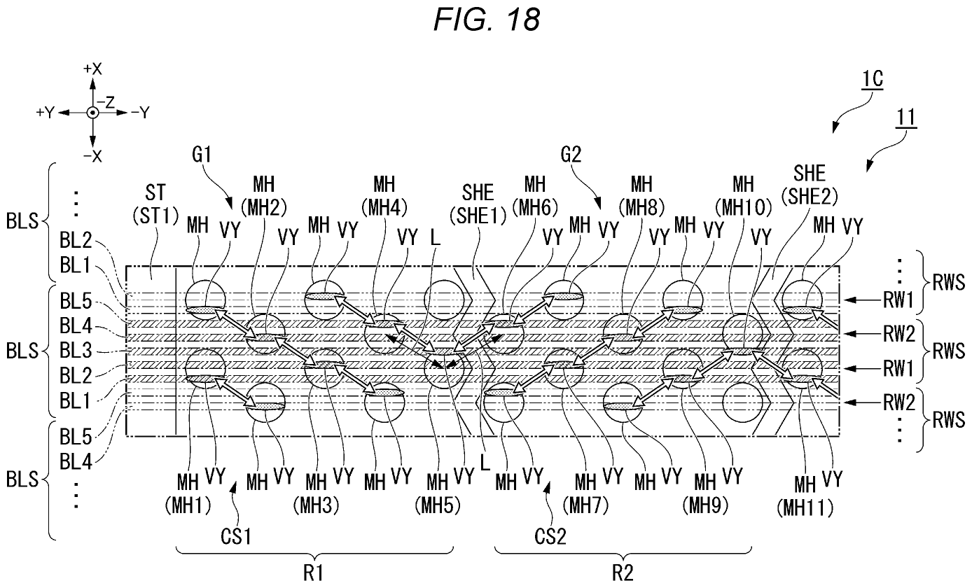

FIG. 18 is a cross-sectional view illustrating a part of a semiconductor memory device 1C of the second modification. In at least one embodiment, when viewed from the Z direction, the dividing portion SHE does not overlap the memory pillar MH. The dividing portion SHE extends in the X direction while repeatedly bending (or bending) between the plurality of memory pillars MH.

Even with the configurations of these modifications, effects similar to those of the first embodiment or the second embodiment can be obtained.

Several embodiments and modifications have been described above. However, the embodiments and modifications are not limited to the examples described above. For example, the number of strings STR located between two adjacent dividing portions ST (that is, the number of strings STR provided in one block BLK) is not limited to four, but may be three or less, or five or more.

According to at least one embodiment described above, the semiconductor memory device has five columnar bodies located in the Y direction in a region between two dividing portions. Regarding each columnar body provided in the above five columnar bodies, there is another bit line provided in the plurality of bit lines between a bit line electrically connected to the columnar body and each bit line electrically connected to the columnar body adjacent to the columnar body at the shortest interval. According to such a configuration, high density can be achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body including a plurality of gate electrode layers and a plurality of insulating layers, wherein the plurality of gate electrode layers and the plurality of insulating layers are alternately stacked one layer at a time in a first direction;
a plurality of columnar bodies extending in the first direction in the stacked body;
a plurality of bit lines disposed on one side in the first direction with respect to the stacked body, located in a second direction intersecting the first direction, and extending in a third direction intersecting with the first direction and the second direction;
a plurality of contacts located between the plurality of columnar bodies and the plurality of bit lines;
a plurality of dividing portions located separately in the third direction, each dividing portion extending in the first direction in the stacked body, and dividing one or more gate electrode layers including the lowermost layer of the plurality of gate electrode layers in the third direction, when the one side is the lower side, wherein
the plurality of columnar bodies includes five columnar bodies which are located alternately in two rows adjacent in the second direction and each columnar body extending in the third direction in a region between two adjacent dividing portions of the plurality of dividing portions, and
regarding each columnar body provided in the five columnar bodies, a separate bit line provided in the plurality of bit lines is present between a bit line disposed in the plurality of bit lines and electrically connected to the columnar body, and each bit line disposed in the plurality of bit lines and electrically connected to a columnar body adjacent to that columnar body at the shortest interval among the five columnar bodies.

2. The semiconductor memory device according to claim 1, wherein
a plurality of regions defined by the plurality of dividing portions includes a first region and a second region adjacent to each other,
the plurality of columnar bodies includes a first columnar body, a second columnar body, a third columnar body, a fourth columnar body, a fifth columnar body, a sixth columnar body, a seventh columnar body, an eighth columnar body, a ninth columnar body, and a tenth columnar body,
the first columnar body, the second columnar body, the third columnar body, the fourth columnar body, and the fifth columnar body are disposed in the first region, located alternately in the two rows, and located in this order with respect to the third direction,
the sixth columnar body, the seventh columnar body, the eighth columnar body, the ninth columnar body, and the tenth columnar body are disposed in the second region, located alternately in the two rows, and located in this order with respect to the third direction,
the plurality of bit lines includes a first bit line, a second bit line, a third bit line, a fourth bit line, and a fifth bit line, and the first bit line, the second bit line, the third bit line, the fourth bit line, and the fifth bit line are located in this order in the second direction,
the first columnar body overlaps the first bit line when viewed from the first direction and is electrically connected to the first bit line,
the second columnar body overlaps the fourth bit line when viewed from the first direction and is electrically connected to the fourth bit line,
the third columnar body overlaps the second bit line when viewed from the first direction and is electrically connected to the second bit line,
the fourth columnar body overlaps the fifth bit line when viewed from the first direction and is electrically connected to the fifth bit line,
the fifth columnar body overlaps the third bit line when viewed from the first direction and is electrically connected to the third bit line,
the sixth columnar body overlaps the fifth bit line when viewed from the first direction and is electrically connected to the fifth bit line,
the seventh columnar body overlaps the second bit line when viewed from the first direction and is electrically connected to the second bit line,
the eighth columnar body overlaps the fourth bit line when viewed from the first direction and is electrically connected to the fourth bit line,
the ninth columnar body overlaps the first bit line when viewed from the first direction and is electrically connected to the first bit line, and
the tenth columnar body overlaps the third bit line when viewed from the first direction and is electrically connected to the third bit line.

3. The semiconductor memory device according to claim 2, wherein
the plurality of regions includes a third region located on the opposite side of the first region with respect to the second region and adjacent to the second region,
the plurality of columnar bodies includes an eleventh columnar body, a twelfth columnar body, a thirteenth columnar body, a fourteenth columnar body, and a fifteenth columnar body,
the eleventh columnar body, the twelfth columnar body, the thirteenth columnar body, the fourteenth columnar body, and the fifteenth columnar body are disposed in the third region, located alternately in the two rows, and located in this order with respect to the third direction,
the eleventh columnar body overlaps the first bit line when viewed from the first direction and is electrically connected to the first bit line,
the twelfth columnar body overlaps the fourth bit line when viewed from the first direction and is electrically connected to the fourth bit line,
the thirteenth columnar body overlaps the second bit line when viewed from the first direction and is electrically connected to the second bit line,
the fourteenth columnar body overlaps the fifth bit line when viewed from the first direction and is electrically connected to the fifth bit line, and
the fifteenth columnar body overlaps the third bit line when viewed from the first direction and is electrically connected to the third bit line.

4. The semiconductor memory device according to claim 1, wherein
the plurality of regions divided by the plurality of dividing portions includes a first region and a second region adjacent to each other,
the plurality of columnar bodies includes a first columnar body, a second columnar body, a third columnar body, a fourth columnar body, a fifth columnar body, a sixth columnar body, a seventh columnar body, an eighth columnar body, a ninth columnar body, and a tenth columnar body,
the first columnar body, the second columnar body, the third columnar body, the fourth columnar body, and the fifth columnar body are disposed in the first region, located alternately in the two rows, and located in this order with respect to the third direction,
the sixth columnar body, the seventh columnar body, the eighth columnar body, the ninth columnar body, and the tenth columnar body are disposed in the second region and located alternately in the two rows, and located in this order with respect to the third direction,
the plurality of bit lines includes a first bit line, a second bit line, a third bit line, a fourth bit line, and a fifth bit line, and the first bit line, the second bit line, the third bit line, the fourth bit line, and the fifth bit line are located in this order in the second direction,
the first columnar body overlaps the third bit line when viewed from the first direction and is electrically connected to the third bit line,
the second columnar body overlaps the fifth bit line when viewed from the first direction and is electrically connected to the fifth bit line,
the third columnar body overlaps the second bit line when viewed from the first direction and is electrically connected to the second bit line,
the fourth columnar body overlaps the fourth bit line when viewed from the first direction and is electrically connected to the fourth bit line,
the fifth columnar body overlaps the first bit line when viewed from the first direction and is electrically connected to the first bit line,
the sixth columnar body overlaps the third bit line when viewed from the first direction and is electrically connected to the third bit line,
the seventh columnar body overlaps the first bit line when viewed from the first direction and is electrically connected to the first bit line,
the eighth columnar body overlaps the fourth bit line when viewed from the first direction and is electrically connected to the fourth bit line,
the ninth columnar body overlaps the second bit line when viewed from the first direction and is electrically connected to the second bit line, and
the tenth columnar body overlaps the fifth bit line when viewed from the first direction and is electrically connected to the fifth bit line.

5. The semiconductor memory device according to claim 4, wherein
the plurality of regions includes a third region located on the opposite side of the first region with respect to the second region and adjacent to the second region,
the plurality of columnar bodies includes an eleventh columnar body, a twelfth columnar body, a thirteenth columnar body, a fourteenth columnar body, and a fifteenth columnar body,
the eleventh columnar body, the twelfth columnar body, the thirteenth columnar body, the fourteenth columnar body, and the fifteenth columnar body are provided in the third region, located alternately in the two rows, and located in this order with respect to the third direction,
the eleventh columnar body overlaps the third bit line when viewed from the first direction and is electrically connected to the third bit line,
the twelfth columnar body overlaps the fifth bit line when viewed from the first direction and is electrically connected to the fifth bit line,
the thirteenth columnar body overlaps the second bit line when viewed from the first direction and is electrically connected to the second bit line,
the fourteenth columnar body overlaps the fourth bit line when viewed from the first direction and is electrically connected to the fourth bit line, and
the fifteenth columnar body overlaps the first bit line when viewed from the first direction and is electrically connected to the first bit line.

6. The semiconductor memory device according to claim 2, wherein
the fifth columnar body and the sixth columnar body are located separately on both sides of one dividing portion disposed in the plurality of dividing portions, and
when viewed from the first direction, a center-to-center distance between the fifth columnar body and the sixth columnar body is the same as a center-to-center distance between the fourth columnar body and the fifth columnar body.

7. The semiconductor memory device according to claim 6, wherein
when viewed from the first direction, the dividing portion overlaps with a part of the fifth columnar body and overlaps with a part of the sixth columnar body.

8. A semiconductor memory device comprising:
a stacked body including a plurality of gate electrode layers and a plurality of insulating layers, wherein the plurality of gate electrode layers and the plurality of insulating layers are alternately stacked one layer at a time in a first direction;
a plurality of columnar bodies extending in the first direction in the stacked body;
a plurality of bit lines disposed on one side in the first direction with respect to the stacked body, located in a second direction intersecting with the first direction, and extending in a third direction intersecting with the first direction and the second direction;
a plurality of contacts located between the plurality of columnar bodies and the plurality of bit lines;
a plurality of dividing portions located separately in the third direction, each dividing portion extending in the first direction in the stacked body, and dividing one or more gate electrode layers including the lowermost layer of the plurality of gate electrode layers in the third direction, when the one side is the lower side, wherein
the plurality of columnar bodies include a first columnar body, a second columnar body, a third columnar body, a fourth columnar body, and a fifth columnar body, and the first columnar body, the second columnar body, the third columnar body, the fourth columnar body, and the fifth columnar body are disposed in a region between two adjacent dividing portions among the plurality of dividing portions, and located in this order in the third direction so as to at least partially overlap each other when viewed from the third direction,
the plurality of bit lines includes a first bit line, a second bit line, a third bit line, a fourth bit line, and a fifth bit line, and the first bit line, the second bit line, the third bit line, the fourth bit line, and the fifth bit line are located in this order in the second direction,
the first columnar body overlaps the first bit line when viewed from the first direction and is electrically connected to the first bit line,
the second columnar body overlaps the fourth bit line when viewed from the first direction and is electrically connected to the fourth bit line,
the third columnar body overlaps the second bit line when viewed from the first direction and is electrically connected to the second bit line,
the fourth columnar body overlaps the fifth bit line when viewed from the first direction and is electrically connected to the fifth bit line, and
the fifth columnar body overlaps the third bit line when viewed from the first direction and is electrically connected to the third bit line.

9. A semiconductor memory device comprising:
a stacked body including a plurality of gate electrode layers and a plurality of insulating layers, wherein the plurality of gate electrode layers and the plurality of insulating layers are alternately stacked one layer at a time in a first direction;
a plurality of columnar bodies extending in the first direction in the stacked body;
a plurality of bit lines disposed on one side in the first direction with respect to the stacked body, located in a second direction intersecting with the first direction, and extending in a third direction intersecting with the first direction and the second direction;
a plurality of contacts located between the plurality of columnar bodies and the plurality of bit lines;
a plurality of dividing portions located separately in the third direction, each dividing portion extending in the first direction in the stacked body, and dividing one or more gate electrode layers including the lowermost layer of the plurality of gate electrode layers in the third direction, when the one side is the lower side, wherein
the plurality of columnar bodies include a first columnar body, a second columnar body, a third columnar body, a fourth columnar body, and a fifth columnar body, and the first columnar body, the second columnar body, the third columnar body, the fourth columnar body, and the fifth columnar body are disposed in a region between two adjacent dividing portions among the plurality of dividing portions, and located in this order in the third direction so as to at least partially overlap each other when viewed from the third direction,
the plurality of bit lines includes a first bit line, a second bit line, a third bit line, a fourth bit line, and a fifth bit line, and the first bit line, the second bit line, the third bit line, the fourth bit line, and the fifth bit line are located in this order in the second direction,
the first columnar body overlaps the third bit line when viewed from the first direction and is electrically connected to the third bit line,
the second columnar body overlaps the fifth bit line when viewed from the first direction and is electrically connected to the fifth bit line,
the third columnar body overlaps the second bit line when viewed from the first direction and is electrically connected to the second bit line,
the fourth columnar body overlaps the fourth bit line when viewed from the first direction and is electrically connected to the fourth bit line, and
the fifth columnar body overlaps the first bit line when viewed from the first direction and is electrically connected to the first bit line.

10. The semiconductor memory device according to claim 1, wherein the semiconductor memory device includes a NAND flash memory.

11. The semiconductor memory device according to claim 1, wherein the gate electrode layers include at least one of tungsten or molybdenum.

12. The semiconductor memory device according to claim 1, wherein the insulating layers include silicon and oxygen.
